(19) United States
(12) Patent Application Publication
(10) Pub. No.: US 2023/0281351 A1
(43) Pub. Date: Sep. 7, 2023

(54) TEMPLATE-BASED LIGHTING DESIGN

(71) Applicant: SIGNIFY HOLDING B.V., Eindhoven (NL)

(72) Inventors: KAITLIN BURKE, ATLANTA, GA (US); NAM CHIN CHO, PEACHTREE CITY, GA (US); WALTEN PETER OWENS, MANLIUS, NY (US); ROBERT BABIARZ, MISSISSAUGA (CA); PARTH JOSHI, ATLANTA, GA (US)

(21) Appl. No.: 18/116,350

(22) Filed: Mar. 2, 2023

Related U.S. Application Data
(60) Provisional application No. 63/316,718, filed on Mar. 4, 2022.

(30) Foreign Application Priority Data
Mar. 15, 2022 (EP) 22162008.1

(51) Int. Cl. G06F 30/13

(52) U.S. Cl. CPC G06F 30/13

(57) ABSTRACT

A template-based lighting design method includes displaying, by a user device, a satellite view image on a display screen, wherein the satellite view image includes a sports area. The method further includes displaying, by the user device, a lighting design template on the display screen, where the lighting design template is overlaid on the sports area, where the lighting design template includes a template frame and one or more light pole markers, where each light pole marker of the one or more light pole markers corresponds to a light pole and one or more light fixtures attached to the light pole, and where the template frame matches an outline of the sports area. The method also includes identifying an existing lighting design based on the lighting design template and parameters associated with the lighting design template.

### CROSS REFERENCE TO PRIOR APPLICATIONS

This application claims the benefit of U.S. Provisional Patent Application No. 63/316,718, filed on Mar. 4, 2022 and European Patent Application No. 22162008.1, filed on Mar. 15, 2022. These applications are hereby incorporated by reference herein.

### TECHNICAL FIELD

The present disclosure relates generally to lighting designs, and more particularly to lighting design for outdoor spaces based on templates.

### BACKGROUND

Lighting design for an outdoor area such as a sports field typically involves examining the outdoor area, and based on desired illuminance, determining type and specification of light fixtures, locations of light poles, light pole heights, orientations of the light fixtures, etc. and estimating the expected illuminance. The process of outdoor area lighting design is typically time consuming. For example, outdoor area lighting design methods typically involve physical presence and measuring the dimensions of an outdoor space. Some outdoor area lighting design methods also involve generating models of an outdoor space and using the models to perform the lighting design. Thus, in some cases, a solution that simplifies the lighting design of outdoor spaces, such as sports fields, may be desirable.

### SUMMARY

The present disclosure relates generally to lighting designs, and more particularly to lighting design for outdoor spaces based on templates. In an example embodiment, a template-based lighting design method includes displaying, by a user device, a satellite view image on a display screen, wherein the satellite view image includes a sports area. The method further includes displaying, by the user device, a lighting design template on the display screen, where the lighting design template is overlaid on the sports area, where the lighting design template includes a template frame and one or more light pole markers, where each light pole marker of the one or more light pole markers corresponds to a light pole and one or more light fixtures attached to the light pole, and where the template frame matches an outline of the sports area. The method also includes identifying an existing lighting design based on the lighting design template and parameters associated with the lighting design template.

In another example embodiment, a lighting design device includes a display screen and a controller. The controller is configured to display a satellite view image on a display screen, where the satellite view image includes a sports area. The controller is further configured to display a lighting design template on the display screen, where the lighting design template is overlaid on the sports area, where the lighting design template includes a template frame and one or more light pole markers, where each light pole marker of the one or more light pole markers corresponds to a light pole having one or more light fixtures attached to the light pole, and where the template frame matches an outline of the sports area. The controller is further configured to identify an existing lighting design based on the lighting design template and parameters associated with the lighting design template.

These and other aspects, objects, features, and embodiments will be apparent from the following description and the appended claims.

### BRIEF DESCRIPTION OF THE FIGURES

Reference will now be made to the accompanying drawings, which are not necessarily drawn to scale, and wherein:

FIG. 1 illustrates a system for performing a template-based lighting design based on a satellite view image according to an example embodiment;

FIG. 2 illustrates a satellite view image of an outdoor area displayed on the user device of FIG. 1 according to an example embodiment;

FIG. 3 illustrates a menu of lighting design templates displayed on the user device of FIG. 1 according to an example embodiment;

FIG. 4 illustrates a light pole having lighting fixtures attached thereto according to an example embodiment;

FIG. 5 illustrates a lighting design template overlaid on the satellite view image shown in FIG. 2 according to an example embodiment;

FIG. 6 illustrates the lighting design template shown in FIG. 5 aligned with a football field included in the satellite view image shown in FIG. 2 according to an example embodiment;

FIG. 7 illustrates parameters associated with the lighting design template shown in FIG. 6 according to an example embodiment;

FIGS. 8 and 9 illustrate another parameter of the lighting design template shown in FIG. 6 according to an example embodiment;

FIG. 9 illustrates the lighting design template shown in FIG. 8 after parameter changes are made according to an example embodiment;

FIG. 10 illustrates illuminance information overlaid on the football field included in the satellite view image shown in FIG. 2 according to an example embodiment;

FIG. 11 illustrates an example of a portion of the illuminance information of FIG. 10 that includes a heat map overlaid on the football field included in the satellite view image shown in FIG. 2 according to an example embodiment;

FIG. 12 illustrates lighting design templates overlaid on the football field and the tennis courts shown in FIG. 2 according to an example embodiment;

FIG. 13 illustrates illuminance information overlaid on the football field and the tennis courts shown in FIG. 2 according to an example embodiment;

FIG. 14 illustrates a portion of the area included in the satellite view image of FIG. 2 that is selected for determining illuminance according to an example embodiment;

FIG. 15 illustrates illuminance information overlaid on the selected portion of the area shown in FIG. 14 according to an example embodiment; and

FIG. 16 illustrates a template-based lighting design method according to an example embodiment.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different drawings may designate like or corresponding but not necessarily identical elements.

### DETAILED DESCRIPTION OF THE EXAMPLE EMBODIMENTS

In the following paragraphs, example embodiments will be described in further detail with reference to the figures. In the description, well-known components, methods, and/or processing techniques are omitted or briefly described. Furthermore, reference to various feature(s) of the embodiments is not to suggest that all embodiments must include the referenced feature(s).

In some example embodiments, a light design method and a light design method may use templates to perform lighting design. The method and device may be used by a lighting professional or a customer to create and visualize a specific sports lighting design based on information such as sports type, number of light poles, illuminance levels, and field size. The method and device may be used in new installation as well as for retrofits. The method and device involve the use of satellite imagery and templates along with configurable parameters to help a user select a desired location in the satellite imagery and find an existing lighting design appropriate for the size of an area (e.g., a sports field), light pole locations, and other requirements.

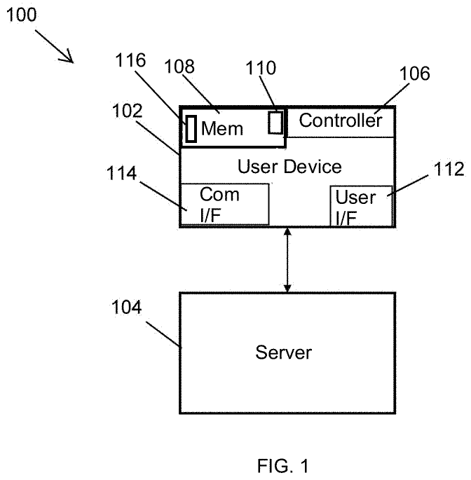

Now turning to the drawings, FIG. 1 illustrates a system 100 for performing a template-based lighting design based on a satellite view image according to an example embodiment. In some example embodiments, the system 100 may include a user device 102 (i.e., a lighting design device) and a server 104. The user device 102 may be communicably coupled to the server 104 via connections that include wired and/or wireless connections. The server 104 may include a map server (e.g., a Google Maps server) that provides satellite view images to the user device 102 for performing template-based lighting design.

In some example embodiments, the user device 102 may include a controller 106 (e.g., a microprocessor or a microcontroller and support components), a memory device 108 (e.g., a static memory device), a user interface 112, and a communication interface 114. A software code 110 may be stored in the memory device 108. Other information including lighting design templates, parameters associated with the lighting design templates, photometric data, etc. may also be stored in the memory device 108. The controller 106 may execute the software code 110 and/or other software code to perform operations described herein with respect to the user device 102. Data 116 such as existing light designs may be stored in the memory device 108. Each existing light design stored in the memory device 108 may include light design information such as number of light poles, number of light fixtures attached to each light pole, light fixture identifiers (e.g., serial number), light fixture orientation (e.g., tilt and pan angles), mount height, optics, photometric data with respect to each light fixture, and other lighting design information that may be required to implement the particular existing lighting design.

In some example embodiments, the user interface 112 may include one or more of a touch-sensitive screen, a keyboard, a mouse, a display screen, and/or another user interface component for receiving user inputs by the user device 102, for displaying information, etc. For example, the user device 102 may be a desktop, a laptop, a table, a smartphone, or another type of user device. The user device 102 may communicate with the server 104 and other devices via the communication interface 114 that may include wired and/or wireless communication components as can be readily understood by those of ordinary skill in the art with the benefit of this disclosure.

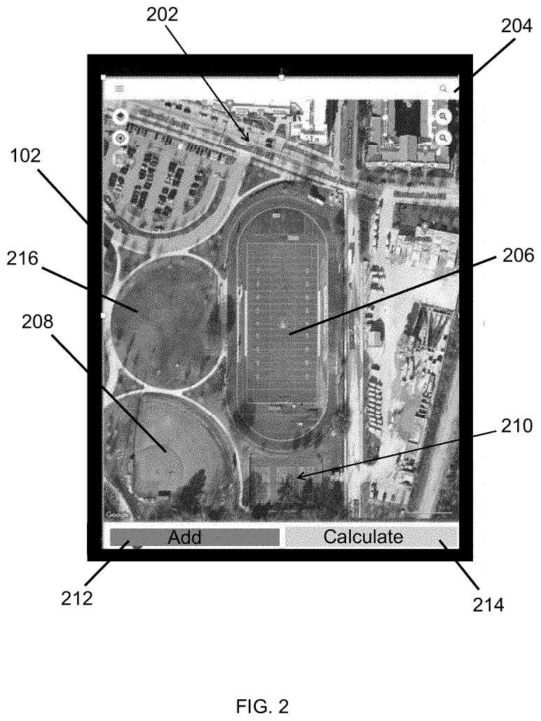

In some example embodiments, a user may operate the user device 102 to display a satellite view image of an area on the user device 102. For example, the user may provide a location (e.g., address) of an area to the user device 102 via the using interface 112, and, in response, the user device 102 may obtain the satellite view image of the area from the server 104 and display the satellite view image, for example on the display screen of the user device 102. FIG. 2 illustrates a satellite view image 202 of an outdoor area obtained from the server 104 and displayed on the user device 102 according to an example embodiment. For example, the satellite view image 202 may be displayed on a screen 204 included in the user interface 112 of the user device 102. The satellite view image 202 shows sports areas such as a football field 206, a baseball field 208, tennis courts 210, and an open field 216 that are in an outdoor area. The satellite view image 202 may be an online or offline interactive image as readily understood by those of ordinary skill in the art with the benefit of this disclosure.

Referring to FIGS. 1 and 2, in some example embodiments, the user device 102 may be used for template-based lighting design of outdoor areas including sports areas such as the football field 206, the baseball field 208, the tennis courts 210, and the open field 216. To illustrate, lighting design templates may be stored in the memory device 108 and may be used to perform lighting design of an outdoor area. The stored lighting design templates may be associated with parameters such as field size, number of light poles, height of light poles and/or lighting fixture mount height, desired illuminance on ground level (e.g., average footcandle), and/or number of courts (e.g., number of tennis courts). Various lighting designs may also be stored in the memory device 108. A lighting design stored in the memory device 108 may include information such as number of light poles, number of fixtures attached to each light pole, type(s) of the light fixtures, light fixture mounting heights, light fixture mounting orientations, and/or other lighting design elements as can be readily understood by those of ordinary skill in the art with the benefit of this disclosure. The lighting designs may be stored in the memory device 108, for example, in relation with sets of values of the parameters associated with light design templates. The controller 106 of the user device 102 may determine that a particular lighting design in the memory device 108 corresponds to a lighting design template based on the values of the parameters associated with the particular lighting design template.

In some example embodiments, the parameters associated with a lighting design template may have default values, and the light design template may correspond to a particular existing lighting design based on the default values of the parameters. If the values of the parameters associated with the lighting design template change, for example, based on a user input to the user device 102, the controller 106 of the user device 102 may determine that the lighting design template corresponds to another existing lighting design based on the new values of the parameters.

In some alternative embodiments, the system 100 may have a different configuration of components than shown without departing from the scope of this disclosure. In some alternative embodiments, the user device 102 may include more, fewer, and/or other components than shown in FIG. 1 without departing from the scope of this disclosure. In some alternative embodiments, some of the operations described above with respect to the controller 106 may be performed by the server 104 without departing from the scope of this disclosure. In some alternative embodiments, information and data may be stored in and/or accessed from the server 104 instead the memory device 108 without departing from the scope of this disclosure.

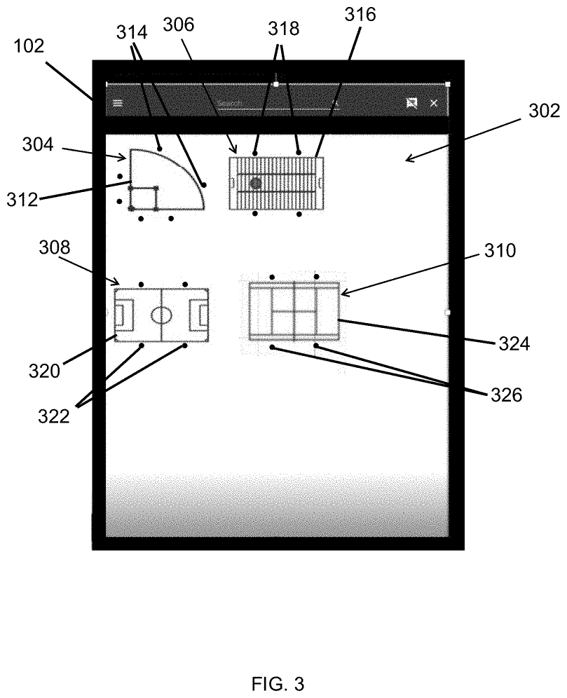

FIG. 3 illustrates a menu 302 of lighting design templates displayed on the user device 102 of FIG. 1 according to an example embodiment. Referring to FIGS. 1-3, the menu 302 may be displayed by the user device 102 in response to a user unput selecting (e.g., touching) Add button 212 on the screen 204 of the user device 102. The lighting design templates in the menu 302 may include a baseball field lighting design template 304, a football field lighting design template 306, a soccer field lighting design template 308, a tennis court lighting design template 310, and/or another lighting design template.

In some example embodiments, the lighting design template 304, 306, 308, 310 may each include a template frame and light pole markers. For example, the baseball field lighting design template 304 may include a template frame 312 and light pole markers such as light pole markers 314. The template frame 312 generally matches the shape of a baseball field such as the baseball field 208 shown in FIG. 2. The light pole markers of the baseball field lighting design template 304 correspond to light poles having one or more light fixtures attached thereto. The light poles may be existing light poles or new ones to be installed. The number of light poles corresponding to the light pole markers of the baseball field lighting design template 304 may be a parameter associated with the baseball field lighting design template 304, and the default value of the number of light poles may be six.

In some example embodiments, the football field lighting design template 306 may include a template frame 316 and light pole markers such as light pole markers 318. The template frame 316 generally matches the shape of a football field such as the baseball field 206 shown in FIG. 2. The light pole markers of the football field lighting design template 306 correspond to light poles having one or more light fixtures attached thereto. The light poles may be existing light poles or new ones to be installed. The number of light poles corresponding to the light pole markers of the football field lighting design template 306 may be a parameter associated with the football field lighting design template 306, and the default value of the number of light poles may be four.

In some example embodiments, the soccer field lighting design template 308 may include a template frame 320 and light pole markers such as light pole markers 322. The template frame 320 generally matches the shape of a soccer field. The light pole markers of the soccer field lighting design template 306 correspond to light poles having one or more light fixtures attached thereto. The light poles may be existing light poles or new ones to be installed. The number of light poles corresponding to the light pole markers of the soccer field lighting design template 308 may be a parameter associated with the soccer field lighting design template 308, and the default value of the number of light poles may be four.

In some example embodiments, the tennis court lighting design template 310 may include a template frame 324 and light pole markers such as light pole markers 326. The template frame 324 generally matches the shape of a tennis court. The light pole markers of the tennis court lighting design template 310 correspond to light poles having one or more light fixtures attached thereto. The light poles may be existing light poles or new ones to be installed. The number of light poles corresponding to the light pole markers of the tennis court lighting design template 310 may be a parameter associated with the tennis court lighting design template 310, and the default value of the number of light poles may be four.

In some example embodiments, the lighting design templates 304-310 may each be associated with one or more parameters such as field size, number of light poles, height of light poles, desired footcandle on ground level (e.g., average footcandle), number of courts (e.g., tennis courts), etc. Each one of the lighting design templates 304-310 may correspond to a respective lighting design based on the default values of the parameters associated with the particular one of the lighting design templates 304-310. For example, the default values of the parameters associated with each one of the lighting design templates 304-310 may correspond to a respective lighting design specifying number of light poles, number of fixtures attached to each light pole, type(s) of the light fixtures, light fixture mounting heights, light fixture mounting orientations, and/or other lighting design elements as can be readily understood by those of ordinary skill in the art with the benefit of this disclosure.

In some alternative embodiments, the menu 302 may include lighting design templates for other sports and multiple sports (e.g., soccer and track). In some alternative embodiments, the menu 302 may include more or fewer lighting design templates than shown in FIG. 3 without departing from the scope of this disclosure. For example, the menu 302 may include an open field template, a parking lot template, etc. without departing from the scope of this disclosure. In some alternative embodiments, the lighting design templates 304-310 may be displayed in a different manner than shown without departing from the scope of this disclosure. For example, names of sports may be displayed instead of or in addition to the lighting design templates 304-310. As another example, values of parameters associated with the lighting design templates 304-310 may be displayed.

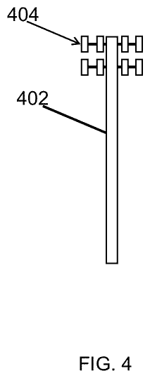

FIG. 4 illustrates a light pole 402 having lighting fixtures 404 attached thereto according to an example embodiment. Referring to FIS. 1-4, in some example embodiments, each of the light pole markers of the football field lighting design template 306 shown in FIG. 3 may correspond to the light pole 402 with the lighting fixtures 404 attached thereto. The football field lighting design template 306 with the associated parameters having a particular set of values may correspond to a lighting design specifying, for example, number of light poles, number of fixtures attached to each light pole, type(s) of the light fixtures, light fixture mounting heights, light fixture mounting orientations, and/or other lighting design elements as can be readily understood by those of ordinary skill in the art with the benefit of this disclosure. The light pole markers of the lighting design template 304, 308, 310 may also correspond to the light pole 402 with the lighting fixtures 404 attached thereto.

In some alternative embodiments, the light pole markers of the lighting design template 304-310 may correspond to the light pole other than the light pole 402 without departing from the scope of this disclosure. In some alternative embodiments, more or fewer light fixtures than shown in FIG. 4 may be attached to the light pole 402. In some alternative embodiments, the light fixtures 404 may be arranged in a different configuration than shown without departing from the scope of this disclosure. In some alternative embodiments, the light fixtures 404 may be attached to the light pole at different mounting heights than shown in FIG. 4 without departing from the scope of this disclosure.

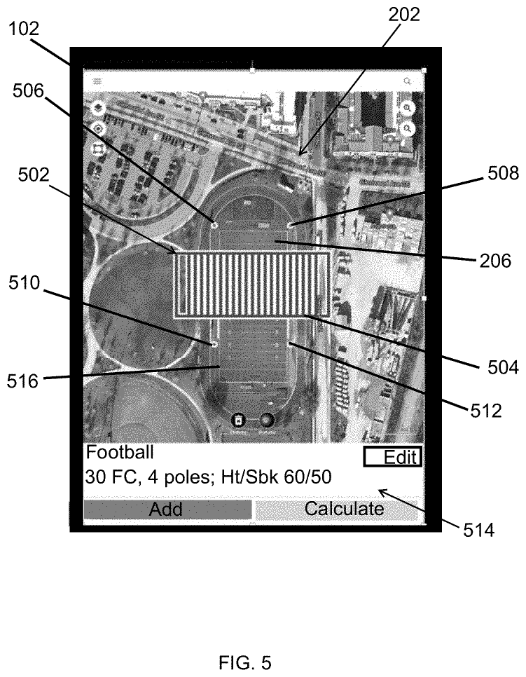

FIG. 5 illustrates a lighting design template 502 overlaid on the satellite view image 202 shown in FIG. 2 according to an example embodiment. For example, the lighting design template 502 may correspond to the football field lighting design template 306 shown in FIG. 3. To illustrate, to perform lighting design for the football field 206, a user may select the football field lighting design template 306 shown in FIG. 3 resulting in the lighting design template 502 being displayed on the user device 102 as shown in FIG. 5. In some example embodiments, the lighting design template 502 may be at a different initial location than shown in FIG. 5.

Referring to FIGS. 1-5, in some example embodiments, the lighting design template 502 includes a template frame 504 and light pole markers 506, 508, 510, 512. The template frame 504 is shaped and sized to match an outline of a football field, which has a standard shape and size. The light pole markers 506-512 correspond to light poles having one or more light fixtures attached thereto. For example, each one of the light pole markers 506-512 may correspond to the light pole 402 with the light fixtures 404 attached thereto. In some alternative embodiments, a different number of light fixtures and/or types of light fixtures may be attached to the light pole 402 with respect to some of the light pole markers 506-512 without departing from the scope of this disclosure.

In some example embodiments, a Summary 514 related to parameters associated with the lighting design template 502 may be displayed on the user device 102. For example, default values of parameters such as illuminance (e.g., 30 Footcandles), number of light poles (e.g., 4), height of light poles (e.g., 60 ft) represented by the light pole markers 506-512, and setback (e.g., 50 ft) of the light poles from an outline of a football field represented by the template frame 504. In some alternative embodiments, the Summary 514 may include more or less information than shown in FIG. 5.

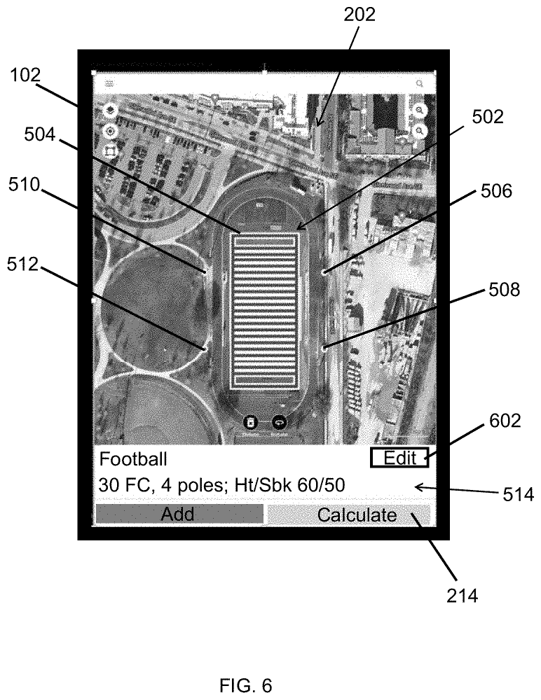

In some example embodiments, the lighting design template 502 displayed on the user device 102 as shown in FIG. 5 may be rotated and/or moved such that the lighting design template 502 is fully overlaid on the football field 206, where the template frame 504 of the lighting design template 502 is aligned with the outline 516 of the football field 206. For example, in contrast to FIG. 5, FIG. 6 illustrates the lighting design template 502 aligned with the football field 206 according to an example embodiment. To illustrate, the user device 102 may rotate and/or move the lighting design template 502 from the position shown in FIG. 5 or from another position to the position shown in FIG. 6.

Referring to FIGS. 1-6, after the lighting design template 502 is overlaid on the football field 206 as shown in FIG. 6 such that the template frame 504 is aligned with the outline 516 of the football field 206, the locations of the light pole markers 506-512 indicate physical locations of light poles corresponding to the light pole markers 506-512. For example, if light poles do not already exist at the physical locations in the area shown in the satellite view image 202, new light poles may be installed at the physical locations.

In some example embodiments, the values of the parameters associated with the lighting design template 502 shown in the Summary 514 may be changed by a user. To illustrate, a user may select (e.g., touch or click) Edit button 602 displayed on the user device 102, which may result in the user device 102 displaying values that can be assigned to the parameters.

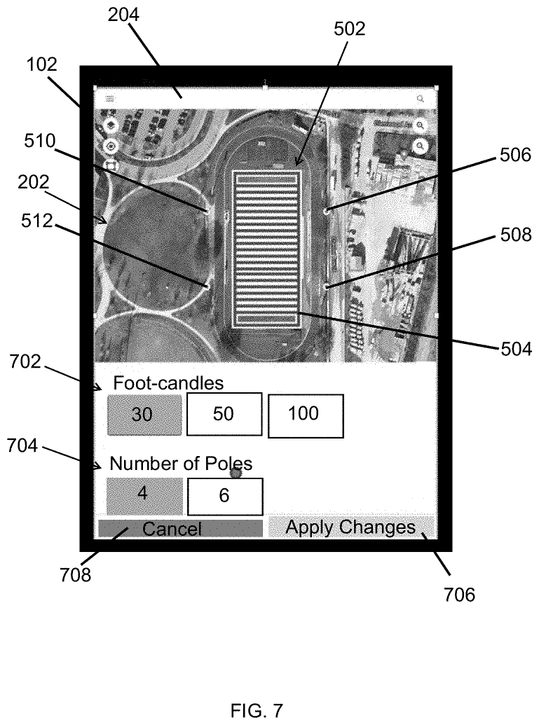

FIG. 7 illustrates parameters associated with the lighting design template 502 shown in FIG. 6 according to an example embodiment. Referring to FIGS. 1-7, in some example embodiments, illuminance (i.e., Foot-candles) 702 may be a parameter associated with the lighting design template 502. For example, Foot-candles 702 may be the desired average illuminance on the football field 206. As another example, Foot-candles 702 may be desired illuminance at a reference location on the lighting design template 502 and thus on the football field 206. A user may provide an input (e.g., a touch or a click) to the user device 102 to change a value of Foot-candles 702. For example, a user may select 50 footcandles (FC) or 100 FC as a value of Foot-candles 702 to change the default value of 30 FC. In some alternative embodiments, other values assignable to Foot-candles 702 may be displayed for user selection without departing from the scope of this disclosure.

In some example embodiments, Number of Poles 704 may be a parameter associated with the lighting design template 502. Number of Poles 704 refers to the number of light poles, existing or new, around the football field 206. Number of Poles 704 corresponds to the number of light pole markers, such as the light pole markers 506-512, of the lighting design template 502, and changing the value of Number of Poles 704 results in changing the number of light pole markers of the lighting design template 502 displayed on the screen 204. To illustrate, if a user selects 6 as a value of Number of Poles 704 instead of the default value of 4, two light pole markers may be displayed on the screen 204 in addition to the light pole markers 506-512. The locations of the light pole markers 506-512 may be changed to accommodate the additional two light pole markers as can be readily understood by those of ordinary skill in the art with the benefit of this disclosure. In some alternative embodiments, other values assignable to Number of Poles 704 may be displayed for user selection without departing from the scope of this disclosure.

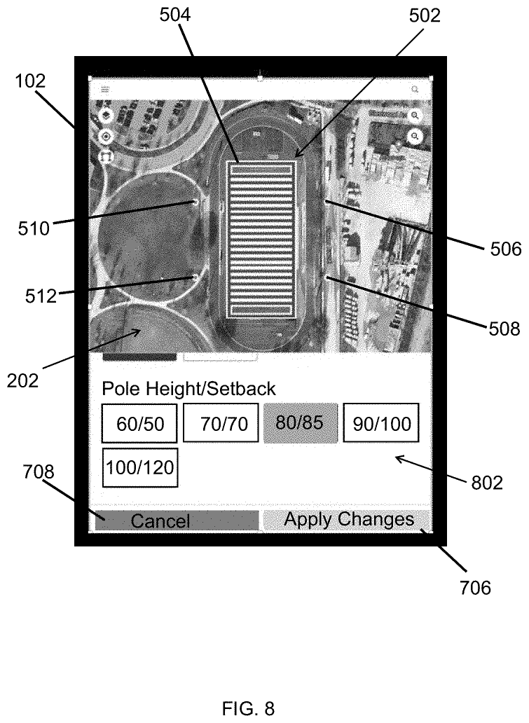

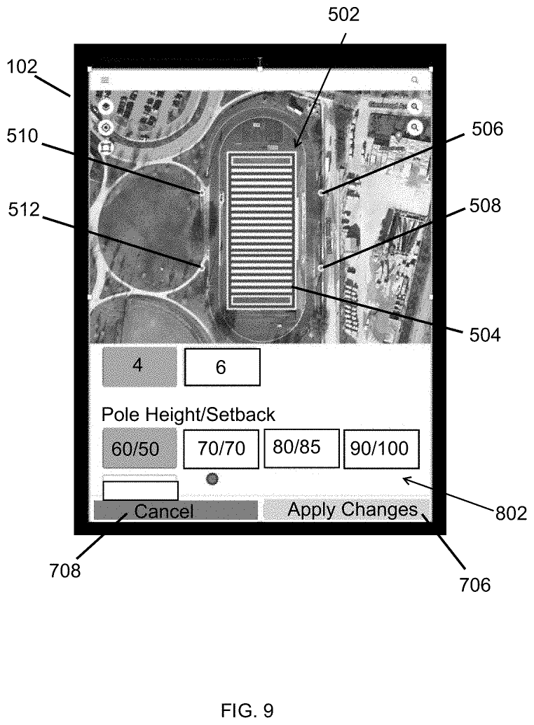

FIGS. 8 and 9 illustrate another parameter of the lighting design template 502 according to an example embodiment. In some example embodiments, Pole Height/Setback 802 may be a pair of parameters, Pole Height and Setback, associated with the lighting design template 502. Pole Height refers to the height (e.g., in feet) of the light poles corresponding to the light pole markers 506-512, and Setback refers to the distance (e.g., in feet) between the light poles corresponding to the light pole markers 506-512 and the outline 516, more clearly shown in FIG. 5, of the football field 206, more clearly shown in FIG. 2. The Setback parameter is represented by the separation between the light pole markers 506-512 and the template frame 504 of the lighting design template 502. Changing the value of Setback may result in a corresponding change in the locations of the light pole markers 506-512 displayed on the screen 204. To illustrate, the locations of the light pole markers 506-512 in FIG. 8, which correspond to Setback having a value of 85 feet, are farther away from the template frame 504 than the locations of the light pole markers 506-512 shown in FIG. 9, which correspond to Setback having a value of 50 feet. In some alternative embodiments, other values assignable to Pole Height/Setback 802 may be displayed for user selection without departing from the scope of this disclosure.

Referring to FIGS. 7-9, in some example embodiments, the user device 102 may assign the user selected values to the parameters, Foot-candles 702, Number of Poles 704, and Pole Height/Setback 802, in response to the user providing an input (e.g., touch or click) to the user device 102 selecting Apply Changes button 706. Alternatively, values may be assigned to the parameters upon the user selecting the values on the user device 102. To cancel changes made to the values of the parameters, the user may provide an input (e.g., touch or click) to the user device 102 selecting the Cancel button 708, and the user device 102 may cancel the changes in response to the user input.

In some example embodiments, values of other parameters may be changeable by a user. For example, when applicable, a size of a field be changed by a user. To illustrate, because baseball fields may have different sizes, options of baseball field sizes may be displayed for selection by a user. In response to a user selecting a particular displayed size, the user device 102 may adjust the size of the corresponding lighting design template (e.g., the baseball field lighting design template 304 shown in FIG. 3) that may be overlaid on a baseball field (e.g., the baseball field 208 shown in FIG. 2). As another example, number of courts may be a parameter that is applicable to lighting design template for tennis (e.g., the tennis court lighting design template 310 shown in FIG. 3).

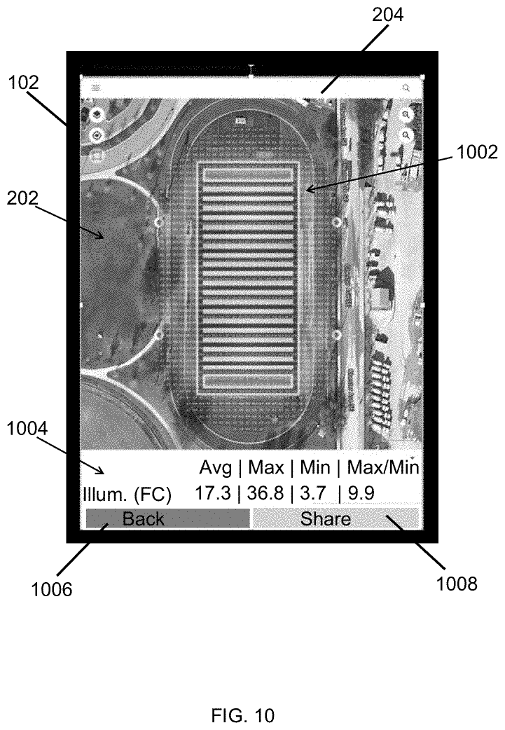

FIG. 10 illustrates illuminance information 1002 overlaid on the football field 206 included in the satellite view image 202 shown in FIG. 2 according to an example embodiment. Referring to FIGS. 1-10, in some example embodiments, the user device 102 may determine illuminance values (e.g., in footcandles) on the football field 206 based on an existing lighting design. For example, the existing lighting design may be selected from among existing lighting designs stored in the user device 102. The user device 102 may identify (i.e., select) an existing lighting design based on the lighting design template 502 and the parameters associated with the lighting design template 502. To illustrate, the user device 102 may select an existing lighting design corresponding to the lighting design template 502 and to the values of the parameters associated with the lighting design template 502.

In some example embodiments, the existing lighting designs may be stored in the memory device 108, for example, in association with values of some or all of the parameters associated with light design templates, such as the light design template 502, to enable the selection of a corresponding existing lighting design from among the existing lighting designs. The existing lighting designs may have been generated based on lighting design operations previous performed for outdoor areas that include sports areas such as football fields, soccer fields, basketball courts, tennis courts, etc. An existing lighting design may include lighting design information such as number of light poles, number of light fixtures attached to each light pole, type(s) of the light fixtures, light fixture identifiers (e.g., serial number), light fixture mounting heights, light fixture mounting orientations, and/or other lighting design elements as readily understood by those of ordinary skill in the art with the benefit of this disclosure. After selecting an existing lighting design, the user device 102 may calculate or otherwise determine illuminance values on the football field 206 based on the selected lighting design.

In some example embodiments, the user device 102 may calculate the illuminance values in response to a user input selecting the Calculate button 214 shown, for example, in FIG. 5 that may be displayed after, for example, after the Apply Changes button 706 is selected by the user. For example, the user device 102 (e.g., the controller 106 shown in FIG. 1) may determine illuminance values on the football field 206 and areas near the football field 206 using the lighting design information specified by the selected lighting design. The user device 102 may use photometric data (e.g., data in IES file(s) stored in the memory device 108) associated with the light fixtures specified by the selected lighting design to determine illuminance values on the football field 206 and areas near the football field 206 as readily understood by those of ordinary skill in the art with the benefit of this disclosure. For example, using photometric data of light fixtures included in the selected lighting design, illuminance values at various locations on and off the football field 206 may be calculated based on the mount heights of the light fixtures on respective light poles and the distances of the various locations from the light poles represented by the light pole markers 506-512. To illustrate, the satellite view image 202 provided by the server 104 shown in FIG. 1 may include location information that enables determining the actual (real-life) distance between two locations in the satellite view image 202.

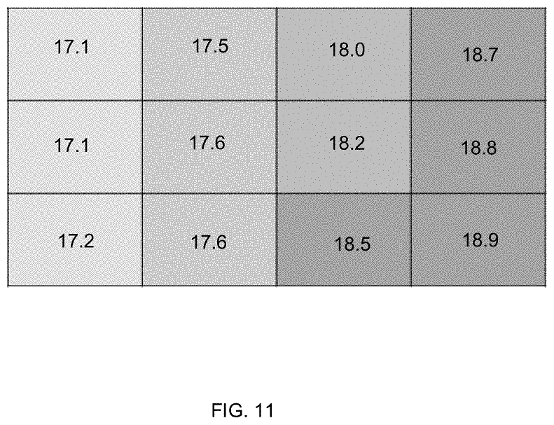

In some example embodiments, the illuminance information 1002 may be displayed overlaid on the football field 206 and areas near the football field 206. For example, the illuminance information 1002 may include a heat map and/or illuminance values. The heat map may represent different illuminance values (e.g., footcandle values) or ranges of illuminance values in respective colors. The color of the heat map at a particular location indicates the illuminance at the particular location, and a particular illuminance value overlaid at a location on the football field 206 indicates the illuminance at the particular location. In some example embodiments, the illuminance information 1002 may include a heat map that represents different illuminance values or ranges of illuminance values in different shades of the same color. FIG. 11 illustrates an example of a portion of the illuminance information 1002 of FIG. 10 that includes a heat map overlaid on the football field 206 included in the satellite view image 202 shown in FIG. 2 according to an example embodiment. In some example embodiments, the illuminance values that are used to generate the heat map or otherwise included in the illuminance information 1002 may be bound at a low end by a minimum threshold value. For example, illuminance values that are less than a minimum threshold value may be excluded from the heat map.

Referring to FIGS. 1-10, in some example embodiments, the user device 102 may display the Illuminance Summary 1004 on the screen 204 of the user device 102 as shown in FIG. 10. For example, average, maximum, and minimum values of the illuminance values may be included in the Illuminance Summary 1004. A ratio of maximum and minimum illuminance values as well as other illuminance related information may be included in the Illuminance Summary 1004. In some alternative embodiments, the Illuminance Summary 1004 may include different, more, or less information than shown in FIG. 10 without departing from the scope of this disclosure.

In some example embodiments, the user device 102 may generate a report that includes lighting design information including a bill of material (e.g., where material is light fixtures) for implementing the selected (existing) lighting design. The report may include the location of the football field 206 (e.g., at the center), the Illuminance Summary 1004 shown in FIG. 1, the type of the sports area/field, light fixture locations (X, Y, Z) with respect to a reference location in the satellite view image 202, orientations of the light fixtures, latitudinal and longitudinal location coordinates of light fixtures, a screenshot of the screen 204 in shown in FIG. 10, and/or other information that enables and facilities the implementation of the selected lighting design at the football field 206. For example, the user device 102 may generate the report automatically, for example, upon the user selecting the Calculate button 214 for the user device to generate the illuminance information 1002.

Tables 1 to 5 below show portions of a sample report that may be generated, automatically or upon a user request, by the user device 102.

TABLE 1

| Location | Latitude | Longitude |
|---|---|---|
| School | 33.50539731750515 | 84.13242671638726 |

TABLE 2
Calculation Summary

| Type | Units | Avg | Max | Min | Avg/Min | Max/Min |
|---|---|---|---|---|---|---|
| Illuminance | FC | 17.3 | 36.8 | 3.7 | 4.7 | 9.9 |

TABLE 3
Sports Field Schedule

| Sport | Design Name | Quantity |
|---|---|---|
| Football | 30 FC-4 | 1 |

TABLE 4
Luminaire Location Summary

| | | | | | | H. | |
|---|---|---|---|---|---|---|---|
| LumNo | Luminaire | Heads | X | Y | Z | Orient. | Tilt |
| 1 | EPH-08-0640L- | 1 | 511 | 449 | 50 | 47.429 | 55.586 |
| | 57-70-3S-VHE | | | | | | |
| 1 | EPH-08-0640L- | 1 | 511 | 449 | 50 | 330.58 | 37.749 |
| | 57-70-4S-VHE | | | | | | |
| 1 | EPH-08-0640L- | 1 | 511 | 449 | 50 | 5.563 | 62.66 |
| | 57-70-2S-VHE | | | | | | |

TABLE 5
Luminaire Coordinates

| LumNo | Luminaire | Latitude | Longitude |
|---|---|---|---|
| 1 | EPH-08-0640L- | 33.50623856851347 | −84.13173472849529 |
| | 57-70-3S-VHE | | |
| 1 | EPH-08-0640L- | 33.50583043665205 | 33.50583043665205 |
| | 57-70-4S-VHE | | |
| 1 | EPH-08-0640L- | 33.50559626907097 | −84.13092293336658 |
| | 57-70-2S-VHE | | |

In some example embodiments, the report generated by the user device 102 may include more, less, or different information than shown in Tables 1 to 5 above. As explained above, the report may include the image displayed on the screen 204 in FIG. 10 or a similar image for other sports areas (e.g., baseball, tennis, basketball, soccer) that shows the illuminance information overlaid in the sports area. In some alternative embodiments, the report generated by the user device 102 may be in a different format than shown in Tables 1 to 5.

In some example embodiments, the user device 102 may send the generated report in response to a user input selecting the Share button 1008. As described above, the report may include the lighting design information of the selected existing design. In general, the lighting design information includes the information specified by the selected lighting design that resulted in the illuminance information 1002 shown in FIG. 10. As described above, information such as light fixture identifier (e.g., serial number), light fixture orientation (e.g., tilt and pan angles), mount height, optics information, etc. with respect to each light fixture may be included. The lighting design information may also include locations of light fixtures and/or light poles (existing or to be installed) in the outdoor area shown in the satellite view image 202. The locations of the light poles correspond to the locations of the light pole markers 506-512 in the satellite view image 202 and may be presented, for example, using Global Positioning System coordinates or other coordinates of the satellite view image 202.

In some example embodiments, as described above, the transmitted lighting design information may also include the illuminance information 1002, the image displayed on the screen 204 as shown in FIG. 10, etc. In general, the user device 102 may transmit lighting design information that enables and facilities the implementation of the selected lighting design at the football field 206. The user device 102 may transmit the information, for example, to a lighting professional, a consumer, and/or a technician.

In some example embodiments, the user may make changes before or after the illuminance information 1002 is displayed. For example, the user may go back to prior pages displayed on the screen 204, for example, to change some of the values of the parameters associated with the lighting design template 502, to remove the lighting design template 502, to add another lighting design template to the satellite view image 202, etc. by selecting the Back button 1006 displayed on the screen 204.

By using existing lighting designs, the light design operations for some outdoor spaces can be simplified. Because locations and distance can be determined from satellite view images, the use of a satellite view image along activity-specific lighting design templates and associated configurable parameters, such as number of light poles and field size (when applicable), enable lighting design operations to be performed without a physical presence at an outdoor location.

In some alternative embodiments, illuminance values may be calculated and stored based on various sets of values of the parameters associated with the different lighting design templates and corresponding lighting designs. In some example embodiments, the lighting design templates (e.g., the lighting design template 304-310), existing lighting designs, photometric data of light fixtures, etc. may be obtained from the server 104 instead of from the memory device 108 without departing from the scope of this disclosure. In some alternative embodiments, the server 104 may also include a lighting design server that may perform light design operations described herein with respect to the user device 102, and the user device 102 may operate as a user interface device between the user and the server 104. In some example embodiments, user inputs may be provided to the user device 102 using means other than selection displayed buttons without departing from the scope of this disclosure.

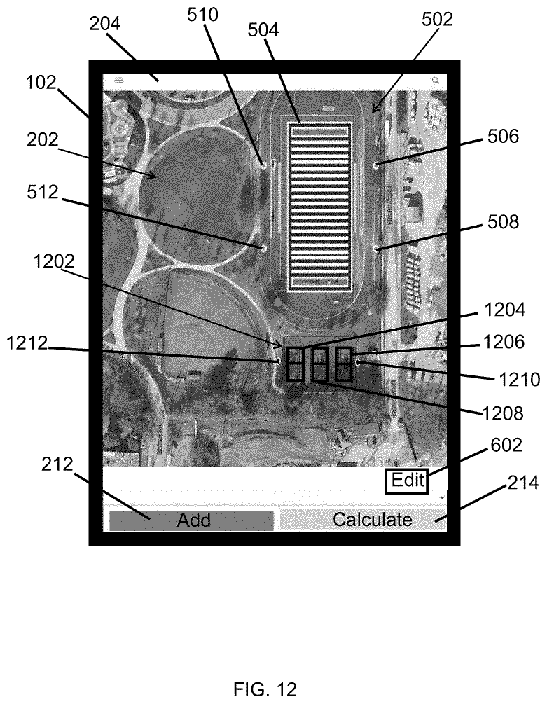

FIG. 12 illustrates lighting design templates overlaid on the football field 206 and the tennis courts 210 shown in FIG. 2 according to an example embodiment. Referring to FIGS. 1-12, in some example embodiments, after the lighting design template 502 is overlaid on the football field 206 as shown in FIGS. 5 and 12, the user may provide an input to the user device 102 by selecting the Add button 212 on the screen 204 of the user device 102. After the menu 302 is displayed on the screen 204 as shown in FIG. 3, the user may select the tennis court lighting design template 310, resulting in a lighting design template 1202 being overlaid on the satellite view image 202. For example, the lighting design template 1202 may include individual court lighting design templates 1204, 1206, 1208 if the default value of the number of courts parameter associated with the lighting design template 1202 is three. The user may rotate and move the lighting design template 1202 as necessary to align each one of the individual court lighting design templates 1204, 1206, 1208 with a respective court of the tennis courts 210. Light pole markers 1210, 1212 correspond to light poles with light fixtures attached thereto. For example, the light pole markers 1210, 1212 may each correspond to the light pole 402, and the locations of the light pole markers 1210, 1212 correspond to locations of existing light poles or locations at which new light poles may be erected.

In some example embodiments, if the default value of the parameter, number of courts, associated with the lighting design template 1202 is not three, the user may change the value by selecting the Edit button 602. The user may then select three as value of the parameter, number of courts, in a similar manner as described above with respect to the parameters associated with the lighting design template 502. The user may also change the values of other parameters such as Foot-candles 702, Number of Poles 704, Pole Height/Setback 802 shown in FIGS. 7 and 8.

In some example embodiments, the user device 102 may determine illuminance values (e.g., in footcandles) on the football field 206 and the tennis courts 210 based on existing lighting designs in the same manner as described above with respect to the football field 206. For example, based on the lighting design template 502 and the values of the parameters associated with the lighting design template 502, the user device 102 may select an existing lighting design from among existing lighting designs stored in the user device 102. Based on the lighting design template 1202 and the values of the parameters associated with the lighting design template 1202, the user device 102 may also select another existing lighting design from among existing lighting designs stored in the user device 102. The user device 102 may select the existing lighting designs in response to a user input selecting the Calculate button 214 or providing another input.

In some example embodiments, the user device 102 may calculate the illuminance values in response to a user input selecting the Calculate button 214. For example, the user device 102 (e.g., the controller 106 shown in FIG. 1) may determine illuminance values on the football field 206, the tennis courts 210, and nearby areas using the lighting design information specified by the selected lighting designs. The user device 102 may use photometric data (e.g., data in IES file(s)) associated with the light fixtures included in the selected lighting designs to determine illuminance values on the football field 206, the tennis courts 210, and nearby areas as readily understood by those of ordinary skill in the art with the benefit of this disclosure. For example, using photometric data of light fixtures specified by the selected lighting designs, illuminance values at various locations on or off the football field 206 and the tennis courts 210 may be calculated based on the mount heights of the light fixtures and the distances of the various locations from the light poles corresponding to the light pole markers 506-512 and the pole markers 1210, 1212.

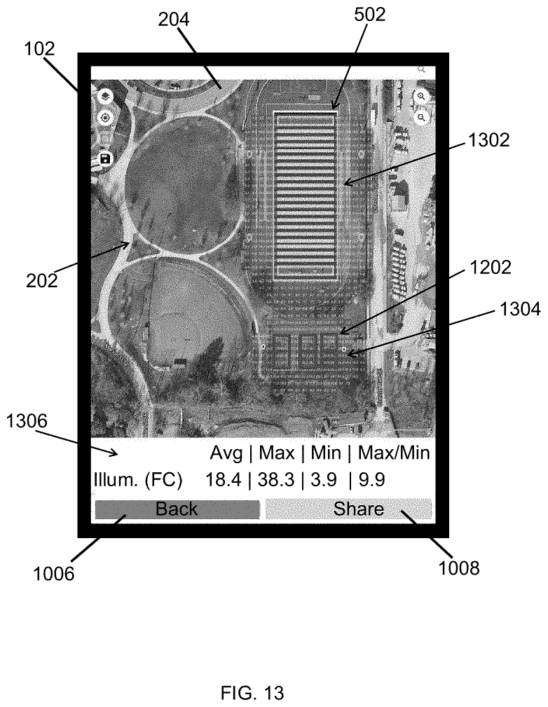

FIG. 13 illustrates illuminance information 1302, 1304 overlaid on the football field 206 and the tennis courts 210 shown in FIG. 2 according to an example embodiment. Referring to FIGS. 1-13, in some example embodiments, the illuminance information 1302 may include a heat map and/or illuminance values overlaid on the football field 206 and nearby areas. The illuminance information 1304 may include a heat map and/or illuminance values overlaid on the tennis courts 210 and nearby areas. The heat maps may represent different illuminance values (e.g., footcandle values) or ranges of illuminance values in respective colors. Alternatively, the illuminance information 1302, 1304 may include heat maps that represents different illuminance values or ranges of illuminance values in different shades of the same color. In some example embodiments, the illuminance values that are used to generate the heat maps and/or included in the illuminance information 1302, 1304 may be bound at a lower end by a minimum threshold value.

In some example embodiments, the user device 102 may display the Illuminance Summary 1306 on the screen 204 of the user device 102 as shown in FIG. 13. For example, average, maximum, and minimum values of the illuminance values may be included in the Illuminance Summary 1306. A ratio of maximum and minimum illuminance values as well as other illuminance related information may be included in the Illuminance Summary 1306. In some alternative embodiments, the Illuminance Summary 1306 may include different, more, or less information than shown in FIG. 13 without departing from the scope of this disclosure.

In some example embodiments, the user device 102 may send the lighting design information of the selected existing designs in response to a user input selecting the Share button 1008. The lighting design information may include the information specified by the selected lighting design that resulted in the illuminance information 1302, 1304 shown in FIG. 13. Information such as light fixture identifier (e.g., serial number), orientation (e.g., tilt and pan angles), mount height, optics information, etc. with respect to each light fixture may be included. The lighting design information may also include locations of light poles (existing or to be installed) in the outdoor area shown in the satellite view image 202. The locations of the light poles correspond to the locations of the light pole markers 506-512 and 1210, 1212 in the satellite view image 202 shown in FIG. 12 and may be presented, for example, using Global Positioning System coordinates or other coordinates of the satellite view image 202.

In some example embodiments, the transmitted lighting design information may also include the illuminance information 1302, 1304, the image displayed on the screen 204 as shown in FIG. 13, etc. In general, the user device 102 may transmit lighting design information that enables and facilities the implementation of the selected lighting design at the football field 206. The user device 102 may transmit the information, for example, to a lighting professional, a consumer, and/or a technician.

In some example embodiments, the user may make changes before or after the illuminance information 1302 and illuminance information 1304 are displayed. For example, the user may go back to prior pages displayed on the screen 204, for example, to change some of the values of the parameters associated with the lighting design templates 502, 1202, to remove one or both of the lighting design templates 502, 1202, to add another lighting design template to the satellite view image 202, etc. by selecting the Back button 1006 displayed on the screen 204.

By determining the illuminance information 1302, 1304 with respect to the football field 206 and the tennis courts 210 (more clearly shown in FIG. 2), the lighting effects that lights intended to illuminate the football field 206 have on the lighting of the tennis courts 210 and vice versa can be considered during the lighting design process. The lighting effects of the lights intended to illuminate the football field 206 and the tennis courts 210 on nearby areas can also be considered during the lighting design process to enable lighting design changes as needed.

In some example embodiments, the template-based lighting design operations described herein may be performed for other sports areas (e.g., the baseball field 208 and/or the open field 216 shown in FIG. 2) instead of or along with the football field 206 and/or the tennis courts 210. In some example embodiments, a satellite view image other than the satellite view image 202 may be displayed on the user device 102. In some example embodiments, the user device 102 may allow zooming in and out to change the portion of the satellite view image 202 that is actively displayed on the screen 204. In some alternative embodiments, user inputs to the user device 102 described herein may be provided to the user device 102 using other means as readily understood by those of ordinary skill in the art with the benefit of this disclosure.

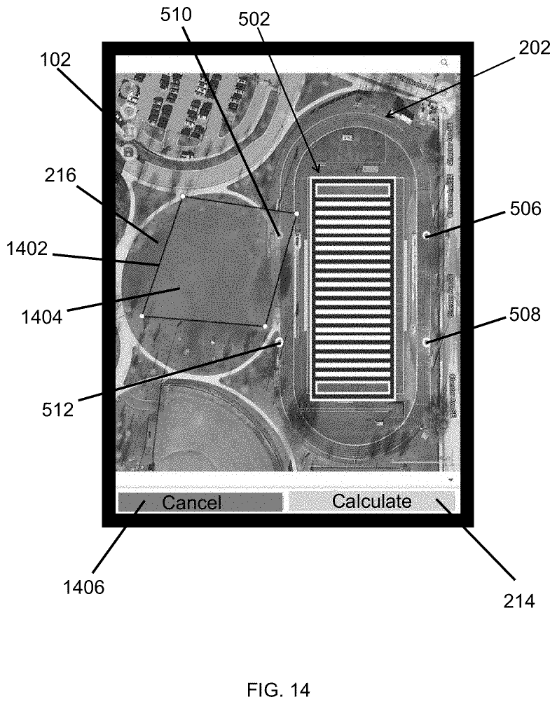

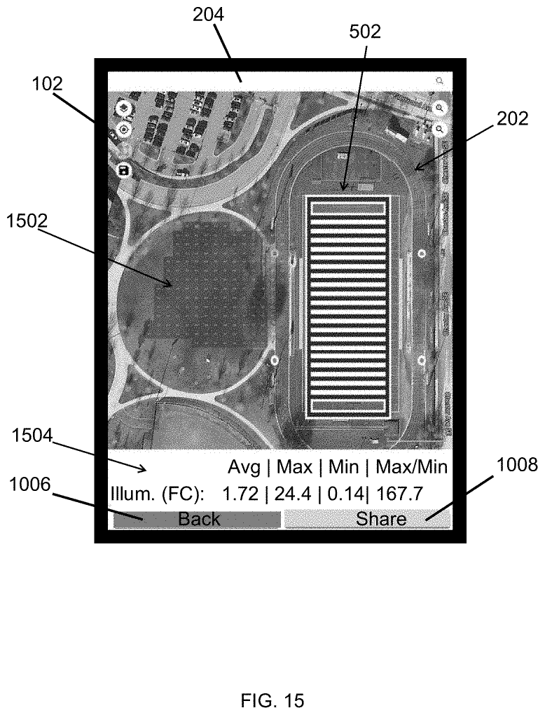

FIG. 14 illustrates a selected area 1404 of the open field 216 included in the satellite view image 202 that is selected for determining illuminance according to an example embodiment, and FIG. 15 illustrates illuminance information 1502 overlaid on the selected area 1404 of the open field 216 shown in FIG. 14 according to an example embodiment. In some example embodiments, the user device 102 may be used to determine effects of a lighting design for one area, such as the football field 206 (shown in FIG. 2), on another area, such as the selected area 1404. To illustrate, after the lighting design template 502 has been overlaid on the football field 206, a user may draw (e.g., using a finger on the screen 204 or using a mouse) a perimeter 1402 around the selected area 1404 to indicate an area of interest for determining spill-over illuminance. The spill-over illuminance may result from a lighting design for the football field 206 selected based on the lighting design template 502 and associated parameters as described above.

In some example embodiments, the user device 102 may calculate the illuminance values for the selected area 1404, for example, in response to a user input selecting the Calculate button 214 shown in FIG. 14. The user device 102 may use photometric data associated with the light fixtures specified by the selected lighting design to determine illuminance values on the selected area 1404. For example, using photometric data of light fixtures included in the selected lighting design, illuminance values at various locations in the selected area 1404 may be calculated based on the mount heights of the light fixtures on respective light poles represented by the light pole markers 506-512 and the distances of the various locations from the light poles as readily understood by those of ordinary skill in the art with the benefit of this disclosure. To illustrate, the satellite view image 202 provided by the server 104 shown in FIG. 1 may include location information that enables determining the actual (real-life) distance between two locations in the satellite view image 202.

In some example embodiments, the illuminance information 1502 shown in FIG. 15 may include a heat map similar to the heat map included in the illuminance information 1002 shown in FIG. 10. The illuminance information 1502 may also include illuminance values overlaid on the selected area 1404, where a particular illuminance value overlaid at a location in the selected area 1404 indicates the illuminance at the particular location. The heat map may be generated based on the illuminance values and may represent different illuminance values (e.g., footcandle values) or ranges of illuminance values in respective colors. The color of the heat map at a particular location in the selected area 1404 indicates the illuminance at the particular location. Alternatively, the illuminance information 1502 may include a heat map that represents different illuminance values or ranges of illuminance values in different shades of the same color.

In some example embodiments, the user device 102 may display Illuminance Summary 1504 on the screen 204 of the user device 102 as shown in FIG. 15. For example, average, maximum, and minimum values of the illuminance values may be included in the Illuminance Summary 1504. A ratio of maximum and minimum illuminance values as well as other illuminance related information may be included in the Illuminance Summary 1504. In some alternative embodiments, the Illuminance Summary 1504 may include different, more, or less information than shown in FIG. 15 without departing from the scope of this disclosure.

In some example embodiments, the user device 102 may transmit the lighting design information of the selected design in response to the user selecting the Share button 1008. If the user wants to make changes, the user may provide an input to the user device 102 by selecting the Back button 1006 and make changes, for example, to the design parameters of the lighting design template 502 and/or perform other operations.

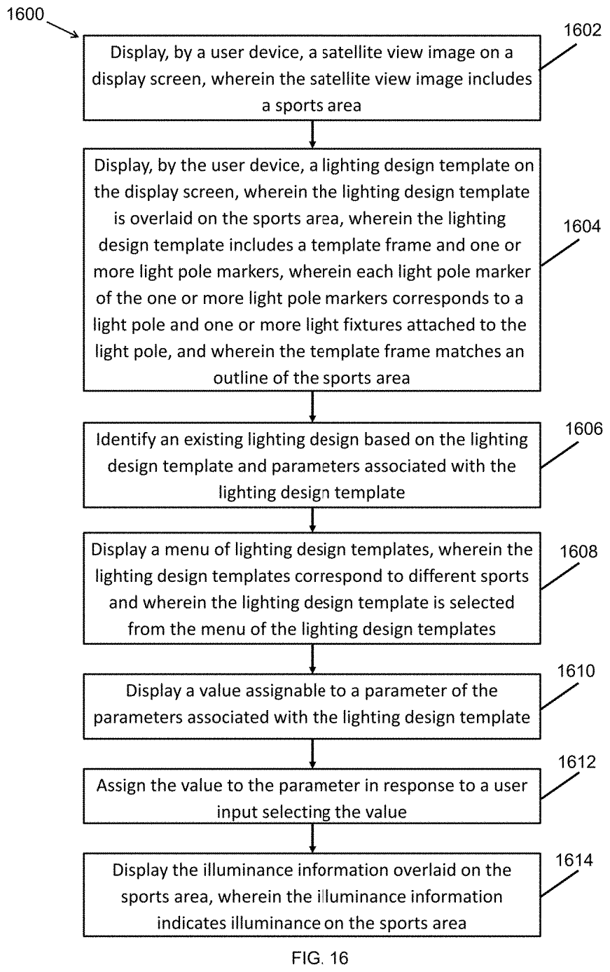

FIG. 16 illustrates a template-based lighting design method 1600 according to an example embodiment. Referring to FIGS. 1-16, in some example embodiments, at step 1602, the method 1600 includes displaying, by the user device 102, a satellite view image 202 on a display screen 204, where the satellite view image includes a sports area, such as the football field 206, the baseball field 208, the tennis courts 210, and the open field 216.

In some example embodiments, at step 1604, the method 1600 includes displaying, by the user device 102, a lighting design template (e.g., the lighting design template 502 or another lighting design template corresponding to the lighting design template 304-310 shown in FIG. 3) on the display screen 204. The lighting design template, such as the lighting design template 502, is overlaid on the sports area (e.g., the football field 206) as shown in FIGS. 6 and 9. The lighting design template (e.g., the lighting design template 502) includes a template frame (e.g., the template frame 504) and one or more light pole markers (e.g., the light pole markers 506-512), where each light pole marker corresponds to a light pole (e.g., the light pole 402) and one or more light fixtures (e.g., the light fixtures 404) attached to the light pole. The template frame (e.g., the template frame 504) matches an outline (e.g., the outline 516) of the sports area (e.g., the football field 206).

In some example embodiments, at step 1606, the method 1600 includes identifying an existing lighting design based on the lighting design template (e.g., the lighting design template 502) and parameters (e.g., Foot-candles 702, Number of Poles 704, and Pole Height/Setback 802, field size) associated with the lighting design template. At step 1608, the method 1600 may include displaying, by the user device 102, a menu (e.g., the menu 302) of lighting design templates (e.g., the lighting design templates 304-310), where the lighting design templates correspond to different sports (e.g., baseball, football, soccer, tennis, and basketball). For example, the lighting design template 502 is selected from the menu 302 of the lighting design templates 304-310, where the lighting design template 502 corresponds to the lighting design template 306.

In some example embodiments, at step 1610, the method 1600 includes displaying, by the user device 102, a value assignable to a parameter of the parameters associated with the lighting design template. For example, values that may be assigned to the parameters, Foot-candles 702, Number of Poles 704, and Pole Height/Setback 802, are shown in FIGS. 8 and 9. At step 1612, the method 1600 may include assigning the value to the parameter in response to a user input selecting the value. For example, a user may select values that are assigned to the parameters as described above, for example, with respect to FIGS. 8 and 9.

In some example embodiments, at step 1614, the method 1600 includes displaying illuminance information overlaid on the sports area (e.g., the football field 206 shown in FIG. 2), for example, as shown in FIG. 10. The illuminance information can be determined at least based on the existing lighting design, where the illuminance information indicates illuminance on the sports area.

In some alternative embodiments, one or more steps of the method 1600 may be omitted without departing from the scope of this disclosure. In some alternative embodiments, one or more steps of the method 1600 may be performed in a different order than described above without departing from the scope of this disclosure. In some alternative embodiments, the method 1600 may include steps than other than those described above without departing from the scope of this disclosure.

Although particular embodiments have been described herein in detail, the descriptions are by way of example. The features of the example embodiments described herein are representative and, in alternative embodiments, certain features, elements, and/or steps may be added or omitted. Additionally, modifications to aspects of the example embodiments described herein may be made by those skilled in the art without departing from the scope of the following claims, the scope of which are to be accorded the broadest interpretation so as to encompass modifications and equivalent structures.

1. A method, comprising:
displaying, by a user device, a satellite view image on a display screen, wherein the satellite view image includes a sports area;
displaying, by the user device, a menu of lighting design templates, wherein the lighting design templates correspond to different sports and wherein a lighting design template is selected from the menu of lighting design templates; and
displaying, by the user device, the lighting design template on the display screen, and aligning the lighting design template to be overlaid on the sports area, wherein the lighting design template includes a template frame and one or more light pole markers, wherein each light pole marker of the one or more light pole markers corresponds to a light pole and one or more light fixtures attached to the light pole, and wherein the template frame matches an outline of the sports area.

2. The method of claim 1, wherein the sports area is a football field, a baseball field, a soccer field, a tennis court, a basketball court, or an empty field.

3. The method of claim 1, further comprising:
identifying an existing lighting design based on the lighting design template and parameters associated with the lighting design template;
displaying, by the user device, a value assignable to a parameter of the parameters associated with the lighting design template; and
assigning the value to the parameter in response to a user input selecting the value.

4. The method of claim 3, further comprising changing, by the user device, a number of the one or more light pole markers displayed on the user device to the value, wherein the parameter is a number of light poles corresponding to the one or more light pole markers.

5. The method of claim 3, wherein the parameter includes a height of one or more light poles corresponding to the one or more light pole markers, wherein the value is assigned as the height of the one or more light poles.

6. The method of claim 3, further comprising changing, by the user device, a size of the lighting design template, wherein the parameter is a size of the sports area.

7. The method of claim 3, further comprising:
determining illuminance information at least based the existing lighting design; and
displaying, by the user device, the illuminance information overlaid on the sports area, wherein the illuminance information indicates illuminance on the sports area.

8. The method of claim 7, further comprising displaying, by the user device, a second lighting design template overlaid on a second sports area included in the satellite view image.

9. The method of claim 8, further comprising determining second illuminance information at least based on a second existing lighting design, wherein the second existing lighting design is selected based on the second existing lighting design template and second parameters associated with the second existing lighting design template.

10. The method of claim 1, further comprising generating, by the user device, a report that includes lighting design information for use in implementing the existing lighting design.

11. A lighting design device, comprising:
a display screen; and
a controller configured to:
display a satellite view image on the display screen, wherein the satellite view image includes a sports area;
display a menu of lighting design templates, wherein the lighting design templates correspond to different sports and wherein a lighting design template is selected from the menu of the lighting design templates; and
display the lighting design template on the display screen, and aligning the lighting design template to be overlaid on the sports area, wherein the lighting design template includes a template frame and one or more light pole markers, wherein each light pole marker of the one or more light pole markers corresponds to a light pole having one or more light fixtures attached thereto, and wherein the template frame matches an outline of the sports area

12. The lighting design device of claim 11, wherein the controller is further configured to:
identify an existing lighting design based on the lighting design template and parameters associated with the lighting design template;
display a value assignable to a parameter of the parameters associated with the lighting design template; and
assign the value to the parameter in response to a user input selecting the value.

13. The lighting design device of claim 11, wherein the controller is further configured to:
determine illuminance information at least based the existing lighting design; and
display the illuminance information overlaid on the sports area, wherein the illuminance information indicates illuminance on the sports area.
